(19) United States
(12) Patent Application Publication
(10) Pub. No.: US 2009/0250000 A1
(43) Pub. Date: Oct. 8, 2009

(54) VACUUM PROCESSING APPARATUS

(76) Inventors: Hiroyuki Kobayashi, Kodaira (JP); Kazuyuki Ono, Hitachinaka (JP); Kenji Maeda, Koganei (JP); Masaru Izawa, Hino (JP); Kenetsu Yokogawa, Tsurugashima (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/193,815

(22) Filed: Aug. 19, 2008

(30) Foreign Application Priority Data
Apr. 4, 2008 (JP) 2008-098193

(51) Int. Cl. C23C 14/00; F04B 49/00

(52) U.S. Cl. 118/50; 137/565.11

(57) ABSTRACT

A vacuum processing apparatus capable of attaining compatibility between the decrease for the number of foreign particles deposited on a sample in a lock chamber and improvement of the throughput, in which an open speed controllable valve is disposed and the depressurization speed can be controlled automatically by a controlling computer.

### CLAIM OF PRIORITY

The present invention claims priority from Japanese Patent Application JP 2008-098193 filed on Apr. 4, 2008, the content of which is hereby incorporated by reference onto the application.

### FIELD OF THE INVENTION

The present invention relates to a vacuum processing apparatus and more in particular to a vacuum processing apparatus having a lock chamber switched between an atmospheric pressure and a vacuum pressure for transferring samples, and vacuum processing apparatus, suitable for use in semiconductor manufacturing apparatus or semiconductor inspection apparatus.

### BACKGROUND OF THE INVENTION

In manufacturing steps for semiconductor devices such as DRAM or micro processors, plasma etching or plasma CVD has been used generally. One of subjects in the manufacture of semiconductor devices includes decrease in the number of foreign particles deposited on a sample to be processed. For examples, when foreign particles drop on the fine pattern of a sample during etching treatment or before etching treatment, the portion is locally hindered from etching. As a result, failure such as disconnection occurs to lower the yield. Accordingly, in the semiconductor manufacturing apparatus or semiconductor inspection apparatus, various methods have been devised so as to prevent foreign particles from dropping on the samples.

For preventing generation of foreign particles due to an abrupt gas stream caused by evacuation in a lock chamber switched between vacuum and atmosphere, a valve for suppressing abrupt depressurization in the chamber by slowly opening a valve has been proposed as described in Japanese Patent Unexamined Publication No. Hei 5 (1993)-237361. The valve is adapted such that one valve can conduct usual exhaust while preventing disturbance of an air flow upon initial exhaust.

Further, it has been proposed as described in Japanese Unexamined Patent Publication No. 11-40549 to conduct exhaust by disposing a low speed exhaust line of low exhaust conductance for gradual vacuum exhaust and a high speed exhaust line of high exhaust conductance and using the low speed exhaust line upon starting vacuum exhaust, such that the depressurization speed does not exceed a predetermined value. JP-A No. Hei 11 (1999)-40549 discloses a constitutional example of serially connecting an exhaust valve and an exhaust conductance control valve capable of binary control to a closed state or open state in one exhaust line and an example of disposing the exhaust valve and the exhaust conductance control valve in parallel in two exhaust lines.

Further, Japanese Unexamined Patent Publication No. 2006-216710 discloses an etching apparatus having a processing chamber, a transfer chamber and a load lock chamber, in which a pressure control is conducted such that the transfer chamber is at a predetermined positive pressure relative to the processing chamber by controlling the gas supply amount and the exhaust speed of the transfer chamber and the processing chamber by a controlling computer, and suppressing the amount of foreign particles deposited on samples by flowing a gas in the processing chamber during transfer of the samples.

FIG. 18 shows an example of a vacuum exhaust system known so far. The system includes a vent line 51, a valve 52 disposed in the vent line (hereinafter referred as a vent valve), a regulator 53, a vacuum transfer chamber 61, an atmospheric air transfer chamber 63, a lock chamber 65, and gate valves 71, 72. Between an exhaust line 140 connected to the lock chamber 65 and a dry pump 144, two exhaust lines, that is, a low speed exhaust line 141 (line along dotted line) for discharging at a low speed (flow rate Q1) upon starting evacuation and a high speed exhaust line 142 for discharging at a high speed (flow rate Q2) after depressurization to some extent (flow amount Q2) are disposed parallel. For the valve 143 disposed to the high speed exhaust line 142 and a valve 145 disposed to the low speed exhaust line, valves not having a function of controlling the on-off speed are used (hereinafter such exhaust line constitution is referred to as 2-stage exhaust structure).

A multi-chamber constitution has now been adopted in vacuum processing apparatus such as plasma processing apparatus. This is a system of connecting plural processing chambers to one set of transfer system for transferring samples. The advantage of the multi-chamber constitution is, for example, that the number of processable sheets of samples per unit of manufacturing apparatus is increased. Accordingly, as the number of processing chambers connected with the transfer chamber is increased from 1 to 2→3→4, it is desirable that the number of processed sheets of samples per unit time increases as twice→three times→four times compared with a case of using one processing chamber. A problem is however, caused that the number of processable sheets of the samples per unit time is not actually increased as expected even when the number of processing chambers is increased. One of the reasons is that improvement in the throughput of the lock chamber is difficult.

For example, in the 2-stage exhaust structure of the existent example shown in FIG. 18, while evacuation of depressurizing from the atmospheric air pressure to vacuum and vent for pressurizing from vacuum to the atmosphere air is conducted in the lock chamber 65, when it is intended to shorten the exhaust time by increasing the speed for vent and evacuation, the speed of air flow in the lock chamber increases to increase the scattering amount of foreign particles. Accordingly, the speed for evacuation or vent cannot easily be increased, and this hinders improvement in the throughput of the lock chamber.

The reason why it is difficult to shorten the exhaust time in the existent 2-stage exhaust structure having two exhaust lines is to be described with reference to FIG. 19 (FIG. 19A-FIG. 19C) and FIG. 20 (FIG. 20A, FIG. 20B).

FIGS. 19A, 19B and 19C show exhaust characteristics of the 2-stage exhaust structure. FIG. 19A shows the opening degree of a valve, FIG. 19B shows the conductance of the exhaust system, and FIG. 19C shows the change with time of pressure in the lock chamber. In FIG. 19A, β1 shows the on-off timing of the valve 145 on the side of the low speed exhaust line in the 2-stage exhaust structure and β2 shows the on-off timing of the valve 143 on the side of the high speed exhaust line in the 2-stage exhaust structure. On the ordinate, CLOSE shows the fully closed state of the valve, whereas OPEN shows the fully open state of the valve. In FIG. 19B, r1 shows the conductance on the side of the low speed exhaust line and r2 shows the conductance of the high speed exhaust line in the 2-stage exhaust structure.

FIG. 19C shows exhaust curves (b1, b2) of the 2-stage exhaust structure, for example, till reaching 30 Pa. That is, at time t6, the valve 145 in the low speed exhaust line is opened to start exhaust from the lock chamber and, at time t7 when the pressure in the lock chamber reaches about 50 kPa, the valve 143 in the high speed exhaust line (large flow rate exhaust) is opened and the valve 145 in the low flow rate exhaust line is closed to conduct exhaust from the high speed exhaust line.

For example, upon depressurization from atmosphere to vacuum by the two-exhaust lines in the 2-stage exhaust structure, the line is controlled for switching, such that exhaust is conducted at a low speed only through the low speed exhaust line from the atmospheric pressure (100 kPa) to about 50 kPa and, subsequently, exhaust is conducted at a high speed only through the high speed exhaust line. In this case, just before the pressure reaches 50 kPa, for example, the exhaust speed in the 2-stage exhaust structure is slower (region ZC in FIG. 19C) compared with that just after starting exhaust (region ZA). This is because the depressurization speed lowers generally as the pressure lowers when the exhaust conductance is fixed. That is, upon evacuation through one low speed exhaust line in the existent 2-stage exhaust structure, the depressurization speed in the region ZC is lowered along with lowering of the pressure in the lock chamber as shown by the exhaust curve (b1) in FIG. 19C since the conductance of the exhaust line is constant as shown by r1 in FIG. 19B.

On the other hand, when it is intended to shorten the exhaust time in the existent 2-stage exhaust structure, it results in a drawback that the depressurization speed on the exhaust curve (b1), for example, just after starting the evacuation (portion for region ZA) exceeds a depressurization speed not generating foreign particles (slant of line SX).

Further, FIG. 20 shows an exhaust curve (b3) upon conducting evacuation through the high speed exhaust line from the start (time t6) as an extraordinary example for promoting evacuation by the existent 2-stage exhaust structure. FIG. 20A shows the opening degree of a valve and FIG. 20B shows the change with time of pressure in the lock chamber.

As can be seen from FIG. 20B, when evacuation is conducted form the start through the high speed exhaust line, while the time (t8) till reaching, for example, 30 Pa is shortened compared with the case of FIG. 19 as shown by (b3), the slant of the exhaust curve, particularly, just after starting exhaust (portion for region ZA in FIG. 20) becomes more abrupt than the depressurization speed (slant of line SX) not causing foreign particles. That is, it involves a drawback that a possibility of generating foreign particles increases extremely.

Further, when the speed of vacuum exhaust is extremely increased, this also results in problems of causing dewing on a sample in the lock chamber and turn-down of a fine pattern, particularly, a resist pattern formed on the sample due to rapid gas flow and they also hinder the improvement of the throughput.

Also the combined structure of the binary value controllable vacuum valve and the exhaust conductance control valve described in JP-A No. 11-40549 involves the same problems as in the existent 2-stage exhaust structure.

Further, while the valve described in JP-A No. 5-237361 can control the time in which the opening degree changes from the fully closed state to the fully open state within an optional range, it does not disclose how to control the exhaust in the lock chamber with a viewpoint of improving the throughput.

### SUMMARY OF THE INVENTION

The present invention intends to provide a vacuum processing apparatus capable of also improving the throughput while decreasing the number of foreign particles deposited on a sample in a vacuum chamber such as a lock chamber switched between a vacuum environment and an atmosphere environment.

One of typical aspects of the present invention provides a vacuum processing apparatus comprising: a vacuum chamber; a vacuum pump for depressurization of the vacuum chamber; a valve disposed in the midway of an exhaust line for connecting the vacuum pump and the vacuum chamber; and controlling device for controlling the opening degree of the valve, wherein the exhaust line is composed of only one line, and the valve disposed in the midway of the exhaust line is composed of only one open speed variable type valve, wherein the controlling device controls the depressurization speed substantially constant upon depressurization of the vacuum chamber from the atmospheric state for the pressure of the vacuum chamber just after starting depressurization to about 50 kPa, and controls the opening degree of the valve such that the depressurization speed is 80 kPa/s or lower.

According to the invention, it is possible to suppress the generation of foreign particles due to evacuation by controlling the exhaust speed, as well as remarkably shorten the time necessary for exhaust, improve the throughput and improve the working efficiency and the productivity of the semiconductor manufacturing and inspection apparatus compared with usual cases.

### DESCRIPTION OF THE ACCOMPANYING DRAWINGS

FIG. 1A is a view showing the outline of a lock chamber disposed in a vacuum processing apparatus of a first embodiment of the present invention;

FIG. 1B is a view showing a constitutional example for an open speed variable type valve disposed in a vacuum exhaust system of the first embodiment;

FIG. 2A is a view showing an example of an entire constitution of a plasma etching apparatus applied with the first embodiment of the invention;

FIG. 2B is a view showing a cross section along line B-B of the plasma etching apparatus in FIG. 2A being observed from the lateral side;

FIG. 2C is a view showing a functional block of a controlling computer in FIG. 2A;

FIG. 3A shows an example for the control of an open speed variable type valve conducted by the controlling computer and shows a control flow when the lock chamber functions as a load lock chamber;

FIG. 3B shows an example for the control of the open speed variable type valve conducted by the controlling computer, and shows a control flow in a case where the lock chamber functions as an unload lock chamber;

FIG. 4 (FIG. 4A, FIG. 4B) is a view showing opening degree characteristics of a valve and an OPEN speed of the valve, that is, a moving speed of a valve body in the first embodiment of the invention;

FIG. 5A is a view showing the state in the midway (one half opening degree for fully open state) in which the open speed variable type valve is open in the first embodiment of the invention;

FIG. 5B is a view showing the outline of the open speed variable type valve substantially in a fully open state in the first embodiment of the invention;

FIG. 6 (FIG. 6A-FIG. 6C) is a view showing comparison for operation characteristics between the open speed variable type valve exhaust structure in the first embodiment of the invention and of the 2-stage exhaust structure by an existent valve,

FIG. 7 (FIG. 7A, FIG. 7B) is a view for explaining the improvement of the throughput according to the invention during evacuation;

FIG. 8 (FIG. 8A-FIG. 8C) is a view showing an example of control characteristics of an open speed variable type valve upon evacuation in a state where the lock chamber functions as an unload lock and wafers are not present in the lock chamber;

FIG. 9A shows an example for the change of pressure during evacuation in the lock chamber when a speed controller is controlled to change the valve OPEN speed and shows the change of pressure for about 8 sec from the start of evacuation;

FIG. 9B is an enlarged view for the change of pressure for a short time of 1 sec from the start of evacuation in FIG. 9A;

FIG. 10 is a view showing the result of an experiment for measuring the number of foreign particles deposited on a wafer under the evacuation condition shown in FIG. 9A and FIG. 9B;

FIG. 11 is a view showing the dependence of the number of foreign particles deposited on the wafer in a lock chamber on the pressure upon switching low speed exhaust and high speed exhaust in a 2-stage exhaust structure;

FIG. 12 is a view showing another example of an open speed variable type valve of the invention;

FIG. 13 is a view showing the control sequence for the valve OPEN speed of an open speed variable type valve of the invention;

FIG. 14A is a view showing a controlling method when the measured value for the depressurization speed is higher relative to an aimed value (predetermined value);

FIG. 14B is a view showing a controlling method when the measured value for the depressurization speed is lower relative to an aimed value (predetermined value);

FIG. 15 is a view simply showing a calculation method for an exhaust time and a vent time in a program incorporated in a controlling computer;

FIG. 16 is a view explaining the method of determining the vent time in the invention;

FIG. 17 is a view showing another example of an open speed variable type valve of the invention;

FIG. 18 is a view showing an example of a vacuum exhaust system known so far;

FIGS. 19A-19C are views showing exhaust characteristics of an existent 2-stage exhaust structure in which FIG. 19A shows an opening degree of a valve, FIG. 19B shows a conductance in the exhaust system, and FIG. 19C shows the change with time of the pressure in the lock chamber; and

FIGS. 20A and 20B show the exhaust curve in a case of promoting the evacuation by the existent 2-stage exhaust structure in which FIG. 20A shows an opening degree of the valve, and FIG. 20B shows a change with time of the pressure in the lock chamber.

### DETAILED DESCRIPTION OF THE PREFERRED EMBODIMENTS

The present invention is to be described by way of preferred embodiments with reference to the drawings.

### Embodiment 1

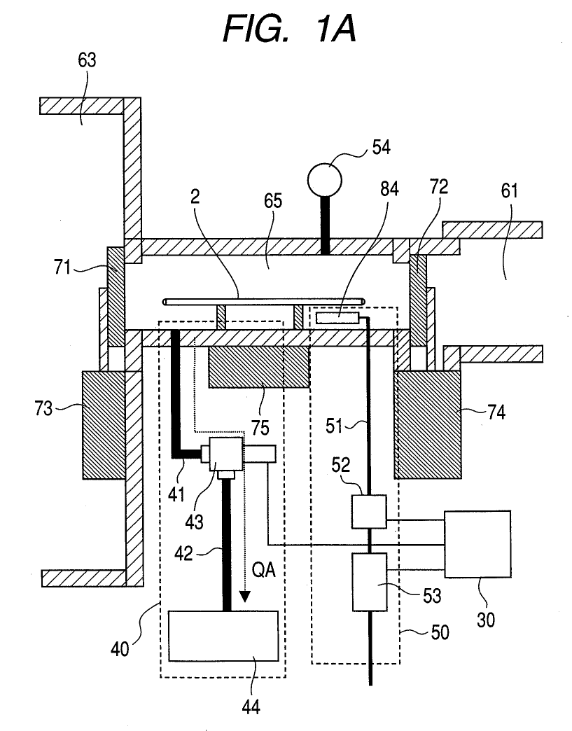

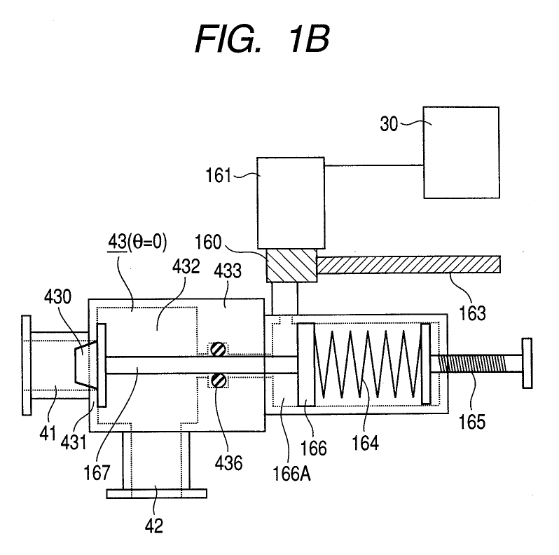

At first, a vacuum processing apparatus according to a first embodiment of the invention is to be described with reference to FIG. 1A to FIG. 11.

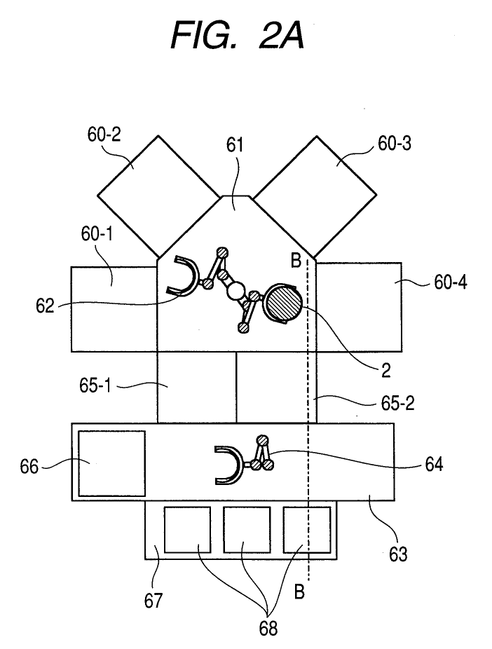

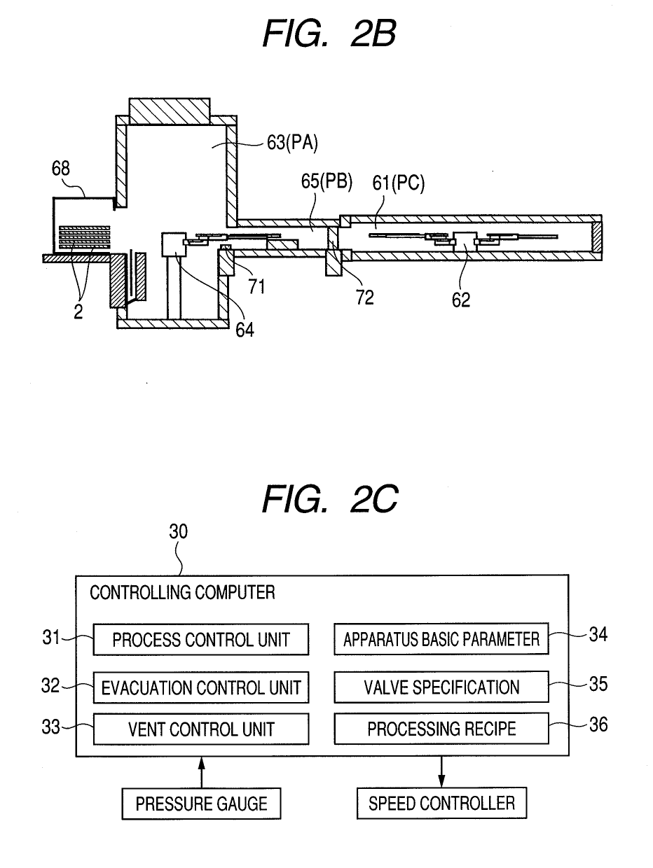

FIG. 1A shows an outline of a lock chamber disposed in a vacuum processing apparatus of the first embodiment. FIG. 1B shows a constitutional example of an open speed variable type valve disposed in a vacuum exhaust system of the first embodiment. FIG. 2A shows an example of the entire structure of a plasma etching apparatus applied with the first embodiment of the invention. FIG. 2B shows a cross sectional view along line B-B of the plasma etching apparatus shown in FIG. 2A as viewed from the lateral side. In FIG. 2B, the plasma processing chamber is not illustrated. Further, FIG. 2C is a view showing functional blocks of a controlling computer in FIG. 2A.

As shown in FIG. 2A, in the plasma processing apparatus of this embodiment, four vacuum processing chambers, that is, plasma processing chambers 60 (60-1 to 60-4) are connected to a vacuum transfer chamber 61. Each of the plasma processing chambers is connected with a depressurization vacuum pump (not shown). A vacuum transfer chamber 61 having a vacuum transfer robot 62 and an atmospheric transfer chamber 63 having an atmospheric transfer robot 64 are connected by way of two lock chambers 65 (65-1, 65-2). For example, the lock chamber 65-1 is a load lock chamber and the lock chamber 65-2 is an unload lock chamber. The load lock chamber is used when a sample 2 is carried-in from the atmospheric transfer chamber to the vacuum transfer chamber, whereas the unload lock chamber is used when the sample 2 is carried-out from the vacuum transfer chamber to the atmospheric transfer chamber. It will be apparent that each of the lock chambers may be used both as a load lock and an unload lock. The atmospheric transfer robot 64 transfers samples 2 sheet by sheet between a FOUP (front opening unified pod) 68 placed in a wafer station 67 and a wafer aligner 66 and the lock chamber 65.

As shown in FIG. 1A, the lock chamber 65 is provided with a vacuum exhaust system 40 having a depressurization vacuum pump (dry pump) 44 and an open speed variable type valve 43 disposed in the midway of exhaust lines 41, 42 for connecting the vacuum pump and the lock chamber. That is, each of the lock chamber 65-1 and the lock chamber 65-2 is connected only by way of one single exhaust line (flow rate QA) with the vacuum pump 44, and the open speed variable type valve 43 is disposed in the midway of each of the exhaust lines.

Further, the lock chamber is connected with a vent gas supply system 50 having a gas diffuser 84, a vent valve 52, and a regulator 53. Reference numeral 30 denotes a controlling device (controlling computer), which controls the degree of the open speed variable type valve 43 and the vent valve 52. Further, a pressure gauge 54 is disposed for measuring the pressure in the lock chamber.

The lock chamber 65-1 and the lock chamber 65-2 are not different in the basic constitution shown in FIG. 1. In addition, for the specific constitution of the plasma etching apparatus, description in JP-A No. 2006-216710 is incorporated hereby by reference.

FIG. 1B shows an example for the constitution of the open speed variable type valve 43 as an exhaust valve disposed in the vacuum exhaust system. The valve is of a type that conducts on-off operation by using a pressurized air, has an inner wall (valve seat) 431 and a valve body 430 disposed at a bent portion of one exhaust line (41, 42), and is controlled for the conductance by adjusting the position of the valve body. FIG. 1B shows a state where the open speed variable type valve 43 is closed. The exhaust valve may be of any structure so long as the conductance of one exhaust line can be controlled by one valve and it goes without saying that this is not restricted to the structure of FIG. 1B.

Upon opening the open speed variable type valve 43, when pressurized air is sent into a region (166A) on the left of a piston in a cylinder relative to a piston 166 connected to the valve body 430, the piston 166 is pushed rightward in the drawing and the valve body moves rightward to attain a valve open state. On the other hand, upon closing the valve, when pressurized air stagnated in the region 166A is drawn, the spring 164 pushes the piston 166 leftward in the drawing to attain a state where the valve body is closed. A pressurized air pipeline 163 is connected by way of a speed controller 160 to the open speed variable type valve 43. The speed controller serves to control the flow rate of the pressurized air supplied to the region 166A in the cylinder. Further, the speed controller 160 can be controlled by a control motor 161 and the control for the speed controller by the motor is conducted by the controlling computer 30 that controls the entire plasma processing apparatus. Although not illustrated in the drawing, it is preferred that an O-ring is disposed at the contact face between the valve body 430 and the inner wall 431 of the valve on the side of the valve body or on the side of the inner wall when the valve body is closed.

The controlling computer 30 has various kinds of functions (units) attained by executing programs by a calculation processing device. That is, as shown in FIG. 2C, it has a process controlling unit 31 for overall control of transfer and processing for samples 2 in the vacuum processing apparatus entirely, an evacuation control unit 32, a vent control unit 33, etc. The evacuation control unit 32 and the vent control unit 33 control the evacuation in the lock chamber or control the vent in the lock chamber under the overall control of the process control unit 31. Further, various kinds of data necessary for executing the programs are stored in a memory. As examples, apparatus basic parameters 34 for vacuum processing apparatus, valve specification 35, vacuum processing recipe 36 to samples, etc. are stored.

The process control unit 31 of the controlling computer 30 controls, for example, the opening degree of the open speed variable type valve 43 in timing with evacuation or vent in the lock chamber along with transfer of samples.

Examples of setting various parameters necessary for the evacuation control unit 32 and the vent control unit 33 are to be described below with reference to subsequent embodiments.

The controlling computer 30 controls the opening degree of the open speed variable type valve 43 upon depressurizing the inside of the lock chamber from the atmospheric state such that the depressurization speed is in a range of 80 kPa/s or lower and 60 kPa/s or higher in a case where a sample is present in the lock chamber. On the other hand, in a case where any sample is not present in the lock chamber, it controls such that the depressurization speed is higher, for example, higher than 80 kPa/s, compared with a case where the sample is present.

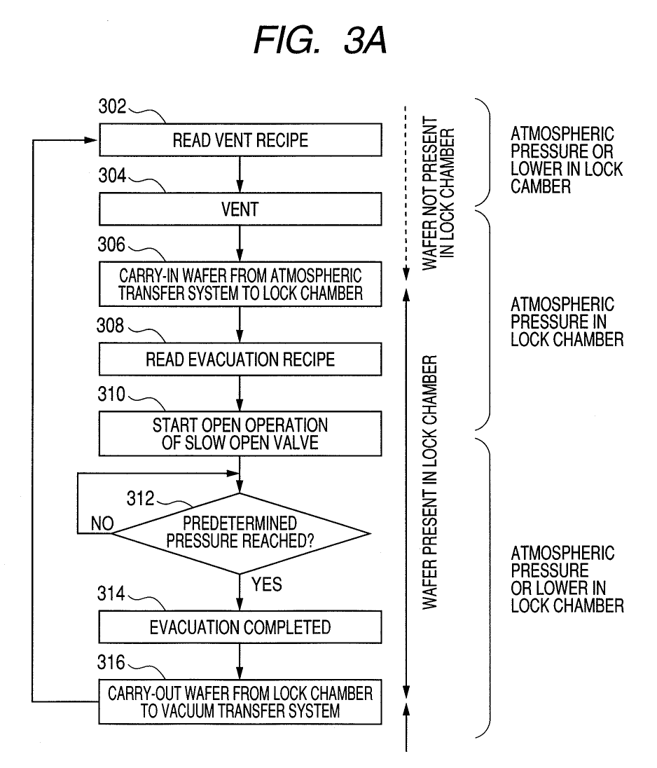

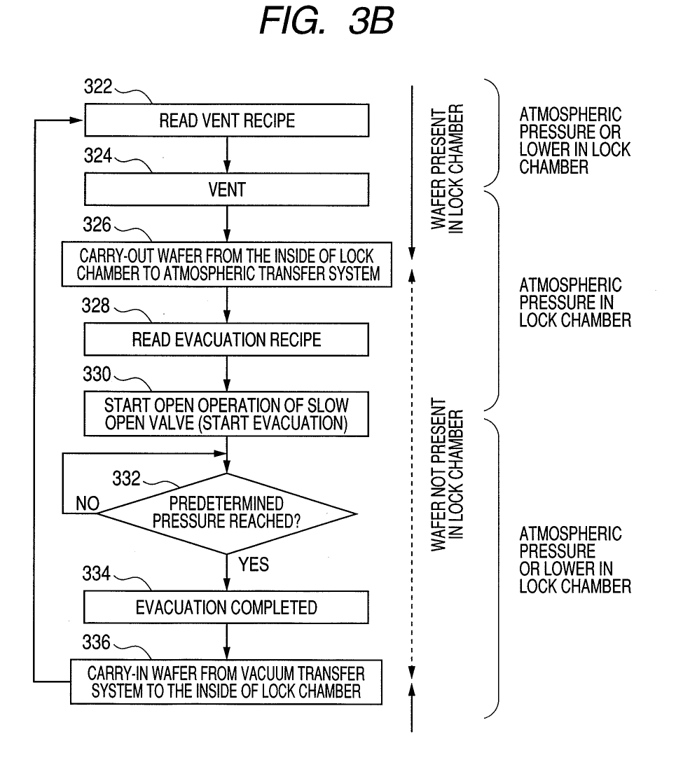

Examples for the control of the open speed variable type valve 43 executed by the controlling computer 30 are to be described with reference to FIG. 3 (FIG. 3A and FIG. 3B) and FIG. 4(A, B). FIG. 3A shows a control flow when the lock chamber functions as a load lock chamber. Further, FIG. 3B shows a control flow when the lock chamber functions as an unload lock chamber. Further, FIG. 4A shows the opening degree of the valve and FIG. 4B shows the valve OPEN speed, that is, the moving speed of the valve body.

The transfer operation for the wafer by way of the lock chamber 65 by the controlling computer 30 is to be described. FIG. 3A shows an operation flow of the evacuation control unit 32 and the vent control unit 33 when the wafer is transferred from the atmospheric transfer system by way of the lock chamber to the vacuum transfer system (61, 62), that is, when the lock chamber functions as a load lock chamber.

At first, for carrying-in a wafer from an atmospheric transfer system (pressure PA) into a lock chamber 65 (pressure PB), the inside of the lock chamber 65 is vented from vacuum to atmosphere. That is, the vent control unit 33 reads a vent recipe such as a supplying amount of a vent gas from the memory in the controlling computer (S302), and supplies the vent gas into the lock chamber 65 while controlling the vent valve 52 and the regulator 53. That is, it conducts a vent processing (S304). Upon vent processing, if the gate valve 72 between the vacuum transfer chamber 61 (pressure PC) and the lock chamber 65 is opened, the gate valve 72 is closed before supplying the vent gas. When the inside of the lock chamber reaches the atmospheric pressure, the gate valve 71 is opened and a wafer is carried-in from the atmospheric transfer system into the lock chamber and the gate valve 71 is closed (S306). Then, for conducting evacuation, the evacuation control unit 32 reads the control recipe for the open speed variable type valve from the memory (S308). Then, evacuation is started in accordance with the control recipe (S310). During evacuation, the pressure in the lock chamber is measured by the pressure gauge 54 and it is monitored as to whether the pressure reaches a predetermined value (for example, 30 Pa) or not (S312) and, when the predetermined pressure is reached, evacuation is completed (S314). Then, the gate valve 72 between the vacuum transfer chamber and the lock chamber is opened to carry-out the wafer toward the vacuum transfer chamber (S316). In a case of continuously transferring wafers from the atmospheric transfer chamber to the vacuum transfer chamber, the flow returns again to (S302).

When the lock chamber functions as the load lock, wafers are present in the lock chamber in a state from (S306) to (S316) in FIG. 3A.

Accordingly, when evacuation is completed (at S314), it is often desired to close the open speed variable type valve so that the pressure in the lock chamber lowers no more. For example, this is a case when the pressure in the vacuum transfer chamber is controlled to a certain constant pressure, for example, 30 Pa.

This is applied based on the technique shown in JP-A No. 2006-216710, because the number of foreign particles deposited to the sample during transfer can be decreased by keeping the state of flowing a gas in the inside of the processing chamber during transfer of a sample (wafer). That is, by suppressing the transfer of the foreign particles by the gas flow, the foreign particles can be prevented from deposition on the sample. In this case, the pressure in the processing chamber is, for example, at 20 Pa. Then, in order not to flow foreign particles or a corrosive gas from the processing chamber to the vacuum transfer chamber, and in order not to form an rapid gas flow upon opening of the gate valve between the processing chamber and the vacuum transfer chamber, the pressure in the vacuum transfer chamber is made somewhat positive relative to the pressure in the processing chamber. The pressure is, for example, at 25 Pa. Then, in order to suppress the generation of the rapid gas flow due to the pressure difference between the vacuum processing chamber and the lock chamber to scatter the foreign particles upon opening the gate valve 72 between the vacuum processing chamber and the lock chamber, it is preferred that the pressure difference between the pressure in the lock chamber and the pressure in the vacuum transfer chamber is about 10 Pa or less. It depends on the operation method as to which pressure should be positive. For example, for merely shortening the evacuation time, it is desired that the pressure in the lock chamber is somewhat positive relative to that in the vacuum transfer chamber. Accordingly, when the pressure in the vacuum transfer chamber is at 25 Pa, no rapid gas flow due to pressure difference is generated by opening the gate valve in a state of setting the pressure in the lock chamber, for example, at 30 Pa.

On the contrary, even after the pressure in the lock chamber has reached, for example, 30 Pa and completion of evacuation has been detected at (S314), if the inside of the lock chamber is depressurized, for example, to 1 Pa or lower by continuing the evacuation, the pressure difference between the lock chamber and the transfer chamber increases to about 25 Pa. When the gate valve 72 is opened in this state, an rapid gas flow is generated due to the pressure difference to increase the possibility of scattering the foreign particles. Therefore, when the pressure in the lock chamber reaches, for example, 30 Pa and the completion of evacuation is detected in the evacuation for the inside of the lock chamber, it is preferred to close the open speed variable type valve and complete the evacuation in the lock chamber.

Then, description is to be made with reference to FIG. 3B for a case where the lock chamber functions as an unload lock chamber. For carrying wafers from the vacuum transfer chamber to the lock chamber, the gate valve 72 is opened in a case where the gate valve 72 is closed and then wafers are carried from the vacuum transfer chamber into the inside of the lock chamber and the gate valve 72 is closed (S336). Then, the vent control unit 33 reads the vent recipe (S322) to conduct vent (S324). When the inside of the lock chamber reaches the atmospheric pressure, the gate valve 71 is opened and the wafers are carried-out to the atmospheric transfer system, and then the gate valve 71 is closed (S326). Then, for evacuating the inside of the lock chamber, the evacuation control unit 32 reads a recipe for evacuation (S328), and opens the open speed variable type valve to conduct evacuation (S330). Then, the pressure in the lock chamber is measured by a vacuum gauge (S332) and, when a predetermined pressure is reached, evacuation is judge to be completed (S334). In the same way as for the explanation in FIG. 3A, when the completion of evacuation has been detected, it is preferred to close the open speed variable type valve and stop evacuation. For attaining continuous unload lock function, the flow returns again to (S336).

As shown in FIG. 3B, when the lock chamber functions as the unload lock chamber, wafers are not present in the lock chamber during evacuation, that is, from (S328) to (S334). Accordingly, even when foreign particles are generated, for example, by peeling from the inner wall during evacuation, they do not possibly contaminate the wafer directly. Accordingly, the OPEN speed of the open speed variable type valve may be increased to shorten the evacuation time in this case. That is, the OPEN speed of the open speed variable type valve may be increased depending on the absence or presence of wafers in the lock chamber. The process control unit 31 that collectively controls the overall transfer and processing of the samples 2 in the vacuum processing apparatus can judge whether the wafers are present or not in the lock chamber based on various kinds of control information. Of course it may be sometimes not desirable to accidentally peel a great amount of foreign particles deposited on the lock inner wall, etc. even when the wafers are not present in the lock chamber and extremely abrupt depressurization is not always necessary.

Further, as another example of the control for the OPEN speed of the open speed variable type valve, intentional abrupt depressurization with an aim of the cleaning effect is sometimes effective. For example, it is also effective to repetitively conduct evacuation accompanying more abrupt depressurization and vent at higher speed during idle time than those in usual wafer transfer thereby once scattering the foreign particles deposited on the inner wall and discharging them together with the gas in the lock chamber from the vacuum pump 44.

As described above, in each of the steps of (S310) in FIG. 3A and (S330) in FIG. 3B, the moving speed of the valve body 430 is controlled by the controlling computer 30 when the open speed variable type valve 43 is opened.

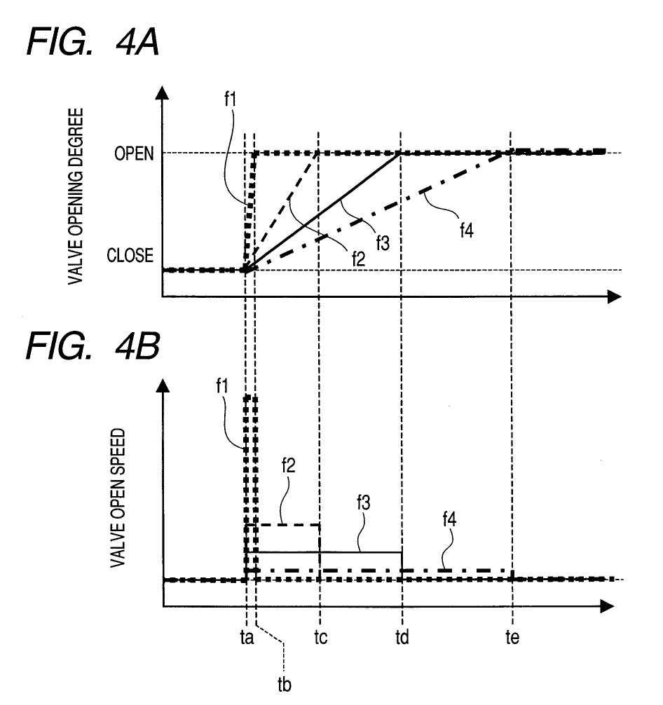

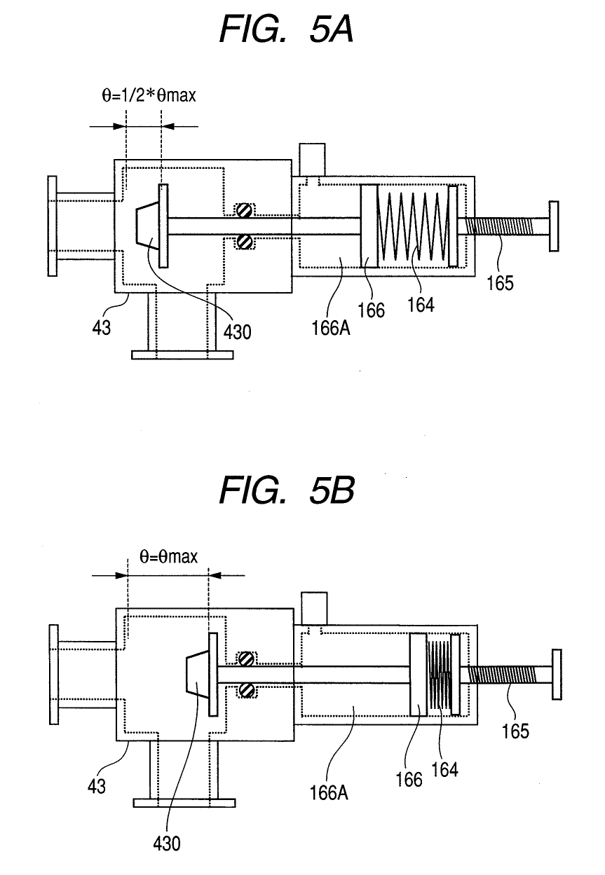

A specific example is described with reference to FIG. 4 (FIG. 4A and FIG. 4B) and FIG. 5 (FIG. 5A and FIG. 5B). FIG. 4A shows the opening degree of the valve and FIG. 4B shows the OPEN speed of the valve, that is, the moving speed of the valve body. Further, FIG. 5A shows the outlined state in the course of opening the open speed variable type valve 43 (about ½ opening degree for the fully open state) and FIG. 5B shows the outlined state when the open speed variable type valve 43 is in a substantially fully opened state.

According to the invention, by controlling the flow rate of the pressurized air supplied to the region 166A in the cylinder by the speed controller 160 controlled by the controlling computer 30, the open speed variable type valve is controlled to such various optional OPEN speeds as characteristics f2, f3, f4, and f1 in FIG. 4. The characteristic f1 shown by a fat broken line in FIG. 4 shows a speed comparable with the on-off speed of a usual valve. In the usual valve, the valve body 430 moves at a high speed to the OPEN position at the same time with the start of OPEN to complete the state of valve OPEN. As the characteristics of the open speed variable type valve 43 of the invention, the characteristic f4, for example, shows a case that the valve OPENs most slowly in FIG. 4. When the moving speed of the valve body is slow as shown by the characteristic f4 in FIG. 4B, the time from the CLOSE position (state in FIG. 1B=ta) to the OPEN position (state in FIG. 5B=te) of the valve body is made longer as shown in FIG. 4A. That is, low moving speed of the valve body during OPEN state (OPEN speed of valve body) means that the time necessary for moving from the CLOSE state to the OPEN state is long.

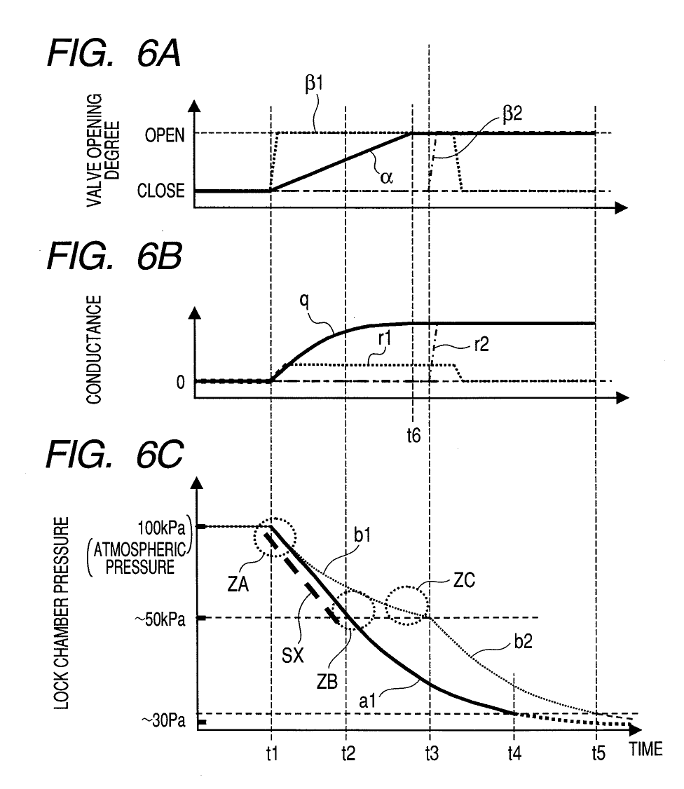

Description is to be made to the advantage of using the open speed variable type valve 43 with reference to FIG. 6 to FIG. 8. Description is to be made, particularly, to the advantage of the open speed variable type valve compared with the existent method in view of the throughput.

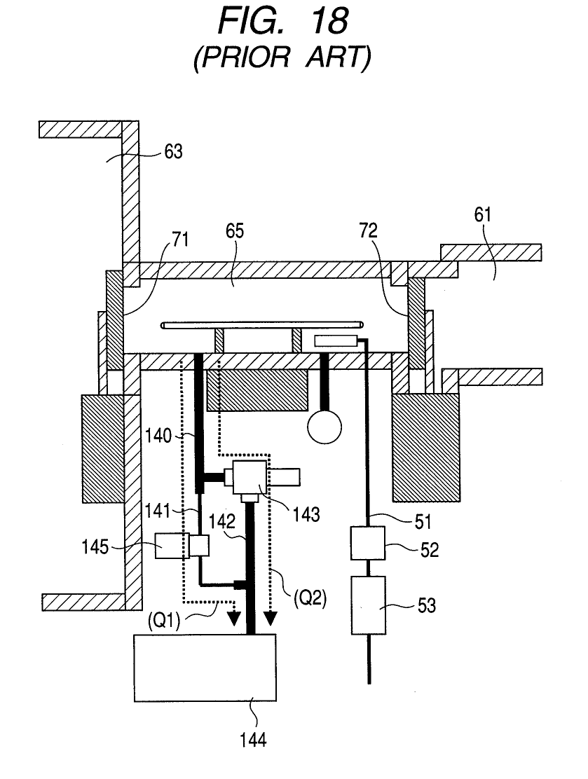

FIG. 6 (FIGS. 6A-6c) shows comparison for the operation characteristics of the open speed variable type valve exhaust structure shown in FIG. 1A and the 2-stage exhaust structure shown in FIG. 18. FIG. 6A shows the opening degree of a valve, FIG. 6B shows the conductance of an exhaust system and FIG. 6C shows change with time of the pressure in a lock chamber.

In FIG. 6A, it is assumed that the line a shows the opening degree of the open speed variable type valve, CLOSE on the ordinate shows the state in FIG. 1B and OPEN shows the state in FIG. 5B. At time t1, the open speed variable type valve starts to open, the opening degree of the valve increases in proportion to the lapse of time, the valve opens fully at time t6 and, subsequently, keeps the fully open state. β1 and β2 show the on-off timing of the valve 145 on the side of the low speed exhaust line and the valve 143 on the side of the high speed exhaust line in the 2-stage exhaust structure.

In FIG. 6B, q shows the conductance in the open speed variable type valve exhaust structure, r1 shows the conductance on the side of the low speed exhaust line, and r2 shows the conductance on the high speed exhaust line in the 2-stage exhaust structure.

In FIG. 6C, a solid line a1 shows an exhaust curve in the open speed variable type valve structure. Further, a fat broken line SX in FIG. 6C shows a necessary depressurization speed (slant of exhaust curve) for suppressing generation of foreign particles which is shown as an index that a possibility for the generation of foreign particles increases abruptly when the slant of the exhaust curve becomes more abrupt than the fat line SX. The value for the slant for SX is, for example, 80 kPa/s.

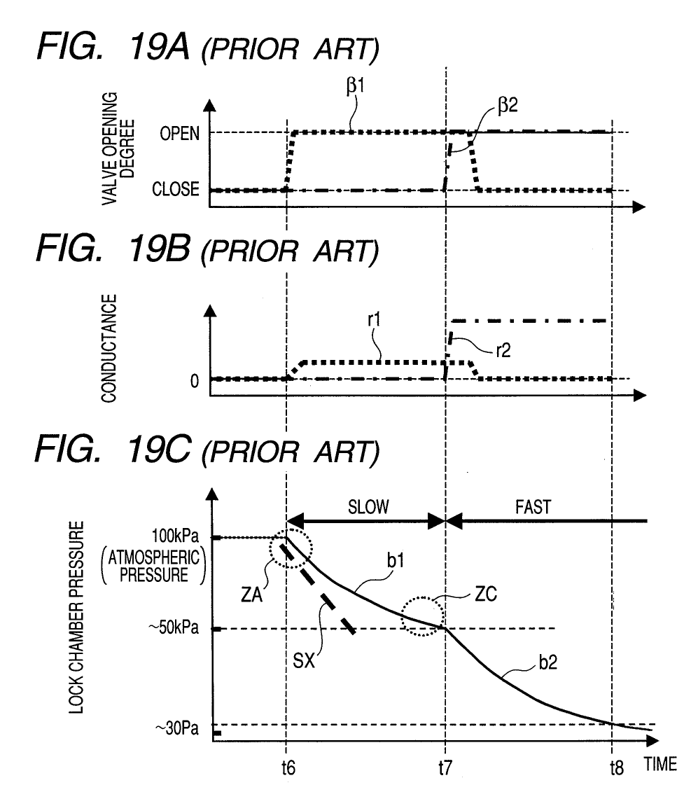

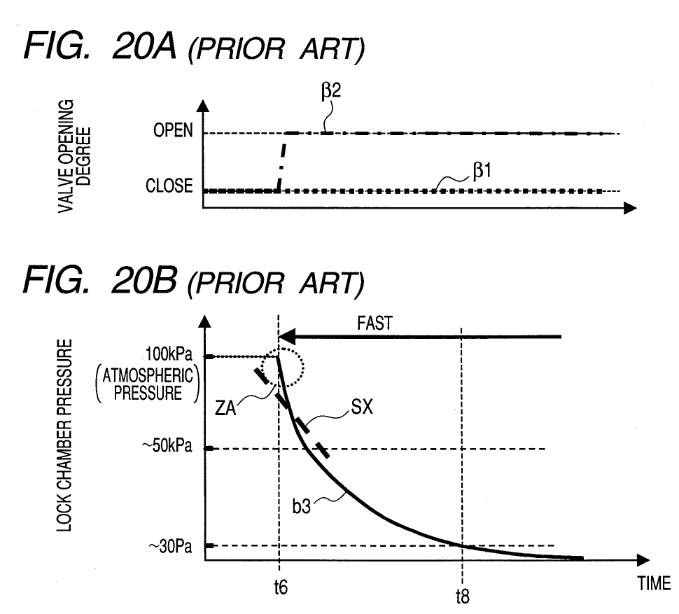

Further, in FIG. 6C, broken lines (b1, b2) are exhaust curves in the 2-stage exhaust structure shown for comparison, which shows a case of switching between the high speed exhaust and the low speed exhaust at 50 kPa (identical with that shown in FIG. 19). In the broken lines, exhaust is conducted through the slow exhaust line for the portion b1 and exhaust is conducted through the high speed exhaust for the portion b2. A portion for the region ZA surrounded by a dotted circle in FIG. 6C shows the exhaust curve just after starting the vacuum exhaust.

At first, in the invention in order not to generate foreign particles just after vacuum exhaust, the exhaust characteristic just after exhaust, that is, the slant for the region ZA is made identical with the fat broken line SX. On the other hand, in the open speed variable type valve exhaust system of the invention, the exhaust speed near 50 kPa (region ZB in FIG. 6C) has no substantial difference compared with that just after starting of exhaust (region ZA). Since the valve body of the valve gradually OPENs as shown at α in FIG. 6A (for example, when the pressure of the lock chamber reaches about 50 kPa, the opening degree of the valve is in a state in FIG. 5A at t2), the exhaust conductance increases gradually as shown at q in FIG. 6B, and the depressurization speed does not lower greatly even when the pressure in the lock chamber lowers.

As has been described above, the exhaust speed in the 2-stage exhaust structure (region ZC in FIG. 6C) is slower just before the pressure reaches, for example, 50 kPa compared with that just after starting of exhaust (region ZA).

Accordingly, the time t2 reaching 50 kPa in the open speed variable type valve exhaust structure of the invention is earlier than the time t3 reaching 50 kPa in the 2-stage exhaust structure. Further assuming the time requiring for evacuation, for example, to 30 Pa as t4 in the open speed variable type valve structure and as t5 in the 2-stage exhaust structure, the difference between t5 and t4 is about of a value close to the difference between t3 and t2, and the open speed variable type valve structure can conduct predetermined evacuation earlier by the difference of the time.

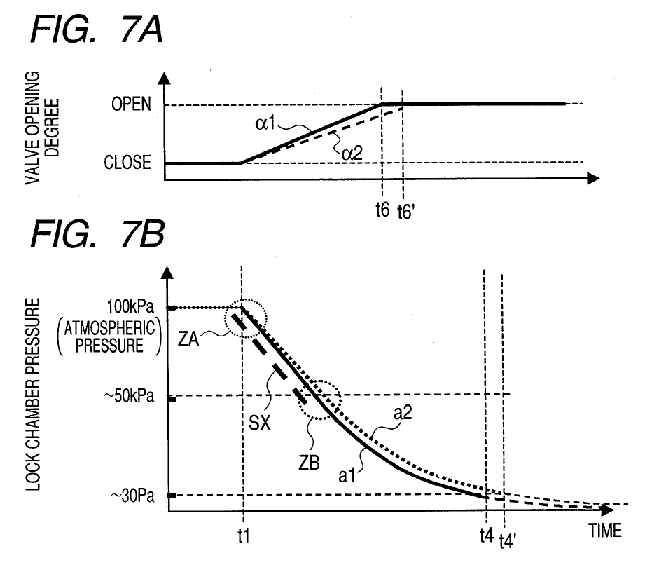

Improvement for the throughput according to the invention is to be described with reference to FIG. 7 (FIGS. 7A, 7B). FIG. 7A shows the opening degree of a valve and FIG. 7B shows the change of pressure with time in the lock chamber. As shown in FIG. 7, when the vacuum chamber is depressurized from the atmospheric state, exhaust is conducted at a low speed for the pressure of the vacuum chamber from just after starting depressurization to about 50 kPa in the invention. In this case, it is desirable to control the upper limit value α1 for the opening degree of the open speed variable type valve 43 by the controlling computer 30 such that the depressurization speed in is the pressure range described above is almost equal with the depressurization speed not generating foreign particles (slant for line SX). Further, the lower limit value α2 for the opening degree is controlled in view of the throughput. That is, so as to improve the throughput while avoiding the possibility for the generation of foreign particles, the opening degree is controlled within a range from α1 to α2, and the depressurization speed from (region ZA) to (region ZB) is controlled within a range from 80 kPa/s (a1) to 60 kPa/s (a2).

In FIG. 7A, while the opening degree a of the valve is indicated by a straight line, it may be a non-linear form substantially approximate to the straight line, for example, it may be of such a characteristic as fluctuating within a range of ±10% with respect to the straight line.

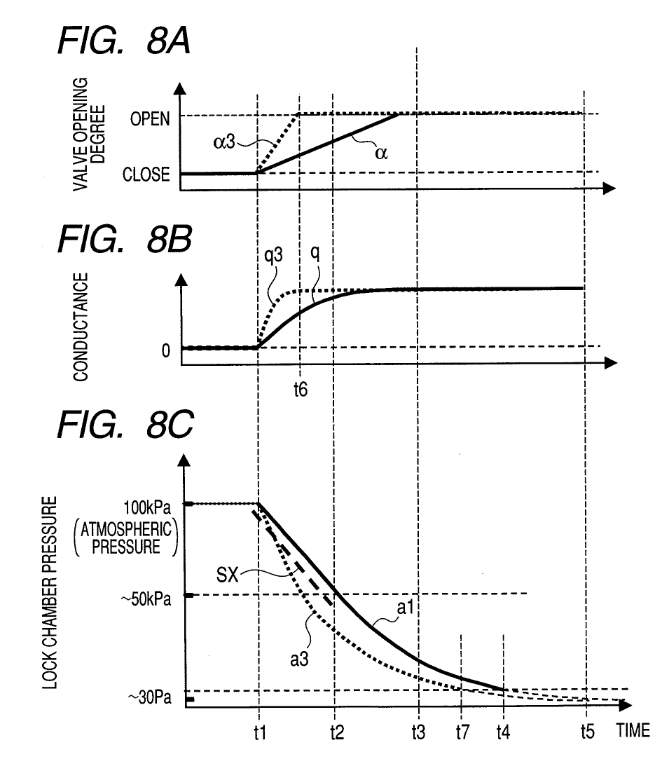

Then, FIG. 8 (FIGS. 8A-8C) shows an example of control characteristics of an open speed variable type valve upon evacuation when the lock chamber functions as an unload lock chamber and wafers are not present in the lock chamber. In a case where there is no possibility that foreign particles directly contaminate wafers upon evacuation, when the OPEN speed of the open speed variable type valve is increased to the opening degree a3, for example, as the characteristic f2 shown in FIG. 4, increase of the exhaust conductance is promoted as in q3, and the slant for the exhaust curve a3 become more steep than that of a fat broken line SX, thereby enabling to shorten the evacuation time. For example, it may be controlled such that the open speed variable type valve is fully opened at time t6 to shorten the time required for evacuation to 30 Pa till time t7.

As described above, it can be seen that the open speed variable type valve exhaust structure of the invention has an advantage capable of shortening the evacuation time while keeping the exhaust speed so as not to generate foreign particles compared with the existent 2-stage exhaust structure.

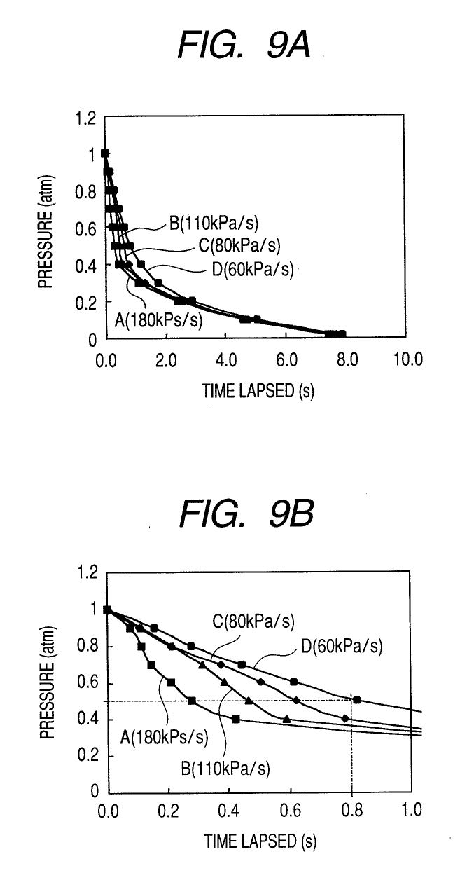

Then, description is to be made to the ground of setting the open degree characteristic of the open speed variable type valve 43 of the invention with reference to FIG. 9A to FIG. 11. FIG. 9A and FIG. 9B show an example of pressure change during evacuation of a lock chamber when the speed controller 160 is controlled to change the OPEN speed of the valve. FIG. 9A shows a pressure change for about 8 sec from the start of evacuation and FIG. 9B shows, in an enlarged scale, the pressure change for a short time of 1 sec from the start of evacuation in FIG. 9A. Both in FIG. 9A and FIG. 9B, the abscissa shows the time of lapse from the start of evacuation and the ordinate shows the pressure in the lock chamber measured by the vacuum gauge 54.

FIG. 9A and FIG. 9B show four types of exhaust curves of A to D and numerical values in parenthesis 9A and 9B show a depressurization speed from 100 kPa (atmospheric pressure) to 50 kPa. The depressurization speed from the atmospheric pressure to 50 kPa is 180 kPa/s for A, 110 kPa/s for B, 80 kPa/s for C, and 60 kPa/s for D.

Such a difference in the depressurization speed can be obtained by controlling the flow rate of the pressurized air by the speed controller 160. In FIG. 9A and FIG. 9B, the depressurization speed is changed by about three times but they are of course values within a range practiced by the experiment and it will be apparent that the depressurization speed can be changed more greatly. Further, as can be seen from FIG. 9A, even when the depressurization speed near the atmospheric pressure is changed within a rang from 60 kPa/s or higher by changing the setting to the speed controller 160, the time reaching from the atmospheric pressure to a pressure, for example, of about 5 kPa or lower is approximately 8 sec and the change of time is as small as within 1 sec. Accordingly, it can be seen that even when the depressurization speed is changed in a range from the atmospheric pressure to about 50 kPa, the throughput concerned with the evacuation of the lock chamber scarcely changes. When the depressurization speed is further decreased to lower than 60 kPa/s, an effect of lowering the throughput develops.

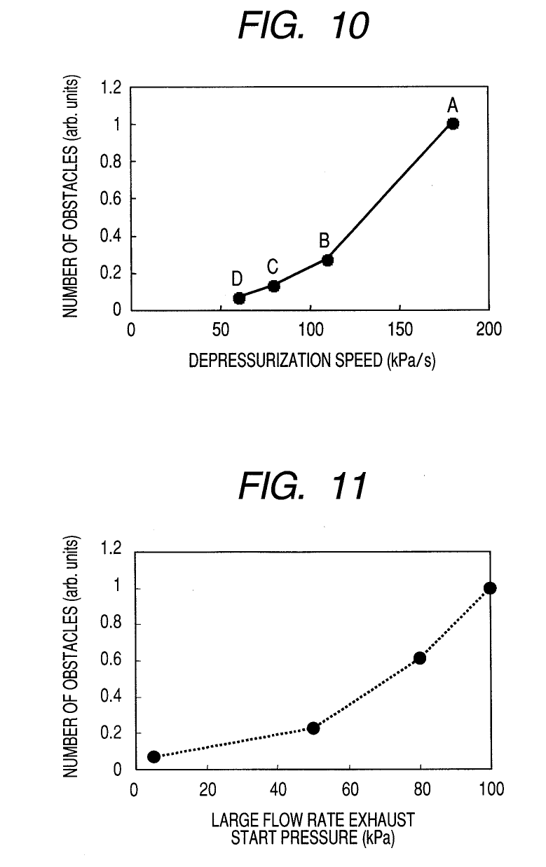

FIG. 10 shows the result of an experiment of measuring the number of foreign particles deposited on a wafer under the evacuation conditions shown in FIG. 9A and FIG. 9B. References A to D in FIG. 10 correspond to conditions A to D in FIG. 9A and FIG. 9B. The abscissa shows the depressurization speed till evacuation from 100 kPa to 50 kPa and the ordinate shows the number of foreign particles, which is indicated being normalized while assuming the number of foreign particles when the depressurization speed is 180 kPa/s (condition A) as 1. In the measurement for the number of foreign particles, vent and vacuum exhaust are conducted repetitively in the lock chamber and the number of foreign particles deposited on the wafer is counted by a face plate inspection device.

As can be seen from FIG. 10, the number of foreign particles deposited to the wafer can be decreased by 80% or more by lowering the depressurization speed from 180 kPa/s to 80 kPa/s. It can be seen that the number of foreign particles can be decreased by 90% or more when the depressurization speed is lowered to 60 kPa/s. In addition, the throughput regarding the evacuation in the lock chamber changes scarcely even when the depressurization speed is lowered in a range of 60 kPa/s or higher. Accordingly, it is preferred to control the depressurization speed till 50 kPa so as to be within a range from 80 kPa/s to 60 kPa/s.

Then, description is to be made on a pressure range in which the depressurization speed should be controlled with a view point of decreasing the foreign particles. FIG. 11 shows the dependence of the number of foreign particles deposited on the wafer in the lock chamber on the switching pressure for low speed exhaust and high speed exhaust. The abscissa shows the pressure upon switching from the low speed exhaust to the high speed exhaust (high flow rate exhaust) and the ordinate shows the number of foreign particles deposited on the wafer. As can be seen from FIG. 11, when exhaust is conduced at a low speed till 50 kPa, the number of foreign particles deposited on the wafer is decreased by about 80% compared with the case of discharging at a high speed all at once from the state of the atmospheric pressure to 100 kPa. That is, for decreasing the number of foreign particles deposited on the wafer due to vacuum exhaust, it can be seen that retardation of the depressurization speed is more important as the pressure is higher, that is, nearer to the atmospheric pressure. More specifically, when the vacuum chamber is depressurized from the atmospheric state, the opening degree of the open speed variable type valve 43 is desirably controlled by the controlling computer 30 such that exhaust is conducted at a low speed from just after starting the depressurization till the pressure of the vacuum chamber reaches about 50 kPa, and the depressurization speed in the pressure range is within a range from 80 kPa/s to 60 kPa/s.

The invention has a feature, particularly, in facilitating the control for the depressurization speed in a region near the atmospheric pressure, by which the number of particles can be decreased easily.

As has been described above according to the invention, by adopting the open speed variable type valve and controlling the exhaust speed of the lock chamber, it is possible to suppress the generation of foreign particles due to evacuation, greatly shorten the time required for exhaust and improve the throughput, and increase the operation efficiency and the productivity of the semiconductor manufacturing and inspection apparatus compared with the existent case.

### Embodiment 2

Embodiment 1 discloses a valve of a type using pressurized air and controlling the moving speed of the valve body by the speed controller as an example of the open speed variable type valve 43, but the valve on-off control method may be those other than using the pressurized air so long as the moving speed of the valve body can be controlled.

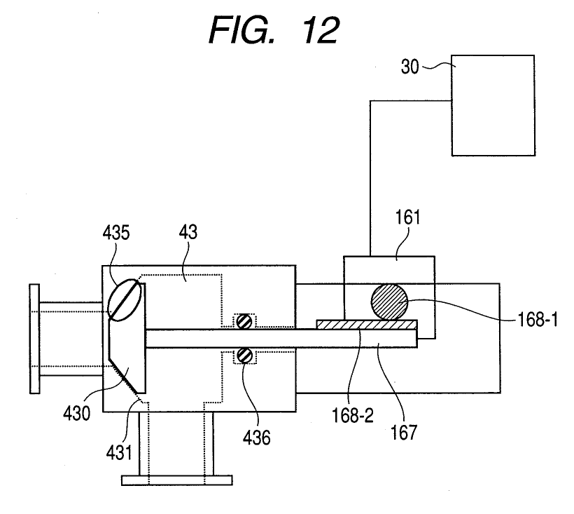

Then, FIG. 12 shows another example of the open speed variable type valve. An open speed variable type valve 43 shown in FIG. 12 is adapted such that a valve body 430 can be controlled directly by a motor 161. When a gear 168-1 connected with a motor is rotated, a shaft 167 connected to a rack gear 168-2 moves rightward and leftward in FIG. 12 thereby opening or closing a valve body 430. The motor 161 is connected to a controlling computer 30 and adapted to control the on-off speed of the valve. Also in this example, the opening degree of the open speed variable type valve 43 is desirably controlled by the controlling computer 30 such that exhaust is conducted at a low speed from just after starting depressurization till the pressure of the vacuum chamber reaches about 50 kPa/s, and the depressurization speed in the pressure range is within a range from 80 kPa/s to 60 kPa/s upon depressurization of the vacuum chamber from the atmospheric state.

Further, when the valve body is configured, for example, to a trapezoidal shape so that the area of the contact surface between a valve body 430 and the inner wall 431 of the valve is made as large as possible when the valve body is closed (region 435 in FIG. 12), this provides an advantage that abrupt increase of the exhaust conductance can be prevented even when the valve body moves slightly rightward from the CLOSE position upon variation of the open speed thereby enabling to fine control for the exhaust speed.

### Embodiment 3

Then, description is to be made for the method of controlling the depressurization speed of the lock chamber by the open speed variable type valve in the invention, that is, a method of acquiring various data stored in the memory as the data for executing the program for controlling the open speed variable type valve.

The depressurization speed of the lock chamber depends not only on the moving speed of the valve body (OPEN speed) but also on the volume on the side of the vacuum chamber, the volume of the pipeline in the exhaust line, and the exhaust performance of the pump. Accordingly, the depressurization speed is controlled by controlling the moving speed of the valve body after assembling the apparatus.

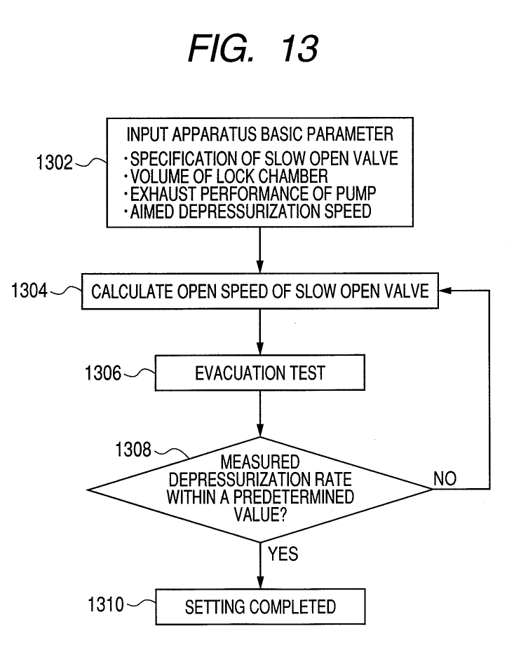

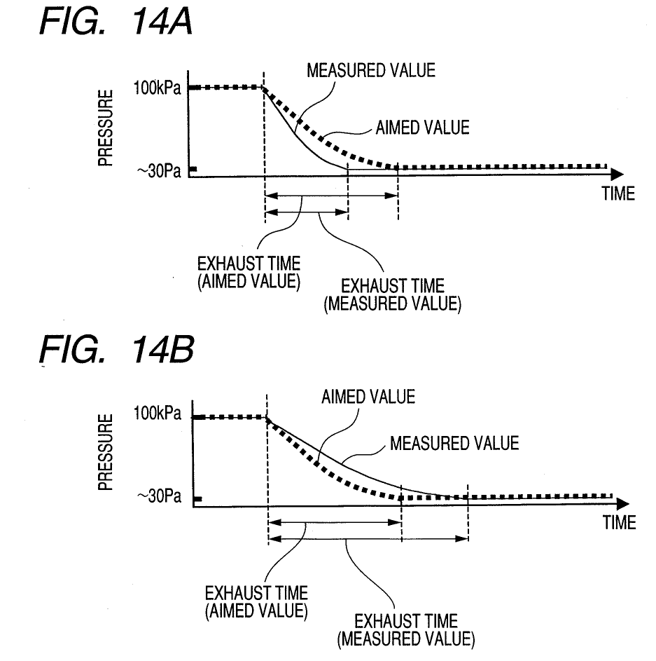

In this invention, this can be controlled by the controlling computer 30. An example of controlling the valve OPEN speed is to be described with reference to FIG. 13 and FIG. 14.

FIG. 13 shows the control sequence of the valve OPEN speed of the open speed variable type valve 43. At first, numerical values such as the volume of the load lock chamber, the valve type, the exhaust performance of the exhaust system, and aimed depressurization speed (for example, depressurization speed of 6×10⁴ Pa/s or lower, for exhaust time of 15 s) are inputted to the controlling computer 30 (S1302). Numerical values for the volume of the lock chamber and the exhaust performance of the exhaust system, etc. may be approximate values. Then, based on the inputted numerical values, the controlling computer 30 calculates the OPEN speed of the valve 43 (S1304). Then, evacuation is conducted actually and the change of pressure is measured by the pressure gauge 54 (S1306). Then the measured pressure change and the predetermined pressure change are compared (S1308). When the result of measurement for the pressure change is within a range of a predetermined value, setting is completed (S1310). If the result is not present within the predetermined range, the valve OPEN speed is controlled, evacuation is conducted again, and the exhaust speed is measured.

For example, as shown in FIG. 14A, when the measured value for the depressurization speed is higher than the aimed value (predetermined value), it is controlled such that the valve OPEN speed is lowered. As shown in FIG. 14B, when the measured value for the depressurization speed is lower than the aimed value, it is controlled such that the valve OPEN speed is made higher. The predetermined range for the depressurization speed means a value at least less than the depressurization speed indicated by the fat broken line SX shown in FIG. 6C and the time is taken, for example, as long as possible within the range.

This is because generation of foreign particles can be suppressed by lowering the depressurization speed but, if the depressurization speed is lowered extremely, it takes much time for evacuation to lower the throughput. Accordingly, it is desirable that the depressurization speed is moderated within a range not lowering the throughput of the entire apparatus.

According to the invention, it is possible to suppress the generation of foreign particles due to evacuation and control the open speed variable type valve and the pressure of the lock chamber so as to improve the throughput.

### Embodiment 4

Further, also in the vent, when the vent speed is increased, foreign particles are scattered to possibly contaminate samples during transfer, values of the time required for the vent and the time required for exhaust have to be decided while considering the total for both of them.

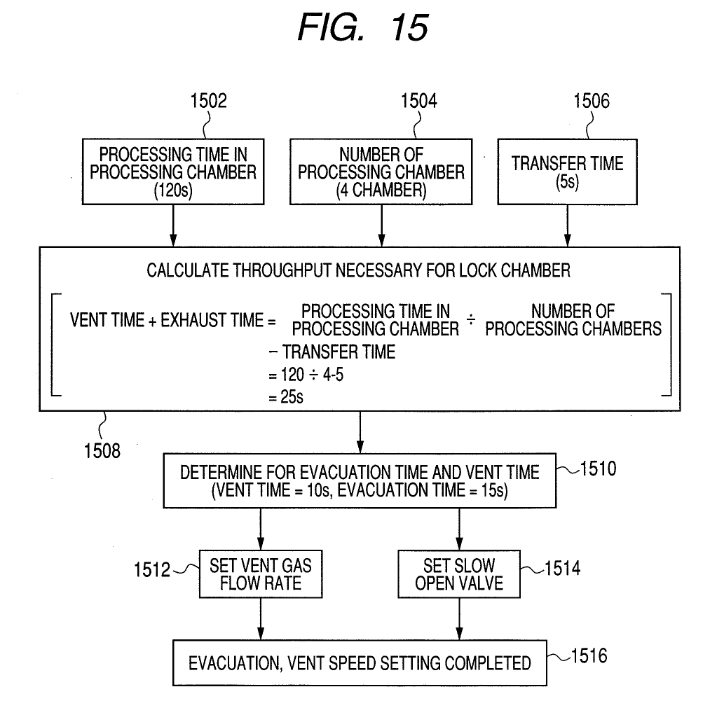

Then, description is to be made to an example of a method for determining the allowable value for the exhaust time and the allowable value for the vent time, that is, a method of acquiring various data stored in a memory as the data for executing a program of controlling an open speed variable type valve with reference to FIG. 15.

FIG. 15 simply shows the method of calculating the exhaust time and the vent time in the program incorporated in the controlling computer 30. Numerical values in blankets in FIG. 15 are examples.

At first, an etching recipe is read and a processing time per one sheet of a sample in a processing chamber is calculated (S1502). Further, the number of operating processing chambers is read as an apparatus parameter from recipe setting or apparatus basic parameter (S1504). Further, also time required for transfer such as the time required for carrying wafers into and out of the lock chamber, etc. are also read, for example, from the apparatus basic parameter (S1506).

Then, the throughput necessary for the lock chamber is calculated based on the processing time, the number of processing chambers, and the transfer time (S1508). For example, when the etching time is 120 sec and the number of processing chambers that operate simultaneously is four, processing for one sheet of wafer is completed in 30 sec. Assuming the transfer time required for carrying wafers into and out of the lock chamber by the transfer robot as 5 sec, the throughput in the lock chamber for processing and transferring wafers with no stagnation (total for evacuation time and vent time in this case) should be 25 sec or less.

Then, the throughput permitted to the lock chamber is allotted to the vent time and the evacuation time (S1510). In a case of using a gas diffuser for the vent gas supply system to suppress the abrupt flow of the vent gas in a predetermined direction, the evacuation time may generally made longer than the vent time. In this embodiment, it is set, for example, such that the vent time is 10 sec and the evacuation time is 15 sec.

When allowable values are determined for the vent time and the evacuation time, the flow rate of the vent gas (S1512) and the OPEN speed of the open speed variable type valve (S1514) are controlled. Control for the open speed variable type valve is as has been described above with reference to FIG. 13 and FIG. 14. As described above, setting for the evacuation and the vent speed is completed (S1516) and the data are recorded in the memory of the controlling computer 30 and used for the control.

FIG. 15 shows only one value of 120 s as an example of the processing time for the samples in the processing chamber. However, in a case of conducting plural different processings separately in parallel on every sample in the plural processing chambers, it may be considered that the completion timing for the processing to the samples is not sometimes constant. That is, the time determined as the throughput of the lock chamber is not sometimes constant. In such a case, the evacuation time or the vent time may be changed on every sample so as not to stagnate the transfer of wafers.

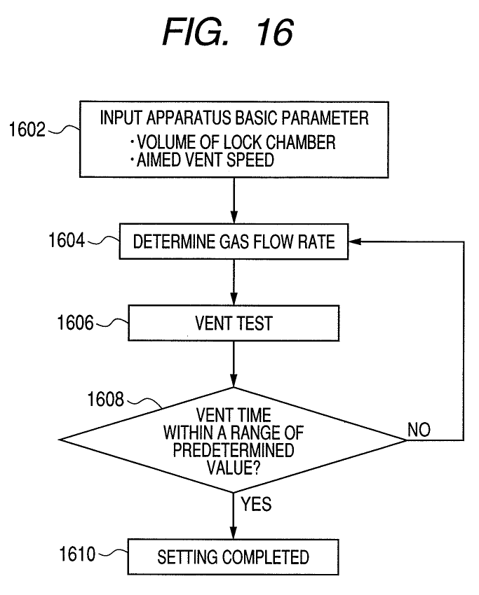

Then, the method of determining the vent time is to be described with reference to FIG. 16. At first, the program of the controlling computer 30 reads the volume of the load lock chamber and the aimed value of the vent time (S1602). Then, the gas flow rate is calculated based on the inputted numerical value (S1604). Then, the vent is conducted actually to measure the vent time (S1606). Then, the measured vent time and the aimed value are compared (S1608). When the vent time is within a range of predetermined values, the setting is completed. If the vent time is not within the predetermined range, control for the gas flow rate and measurement for the vent time are conducted and control is repeated till they are within the predetermined range. As described above, setting for the vent speed is completed (S1610) and the data are recorded in the memory of the controlling computer 30 and used for the control.

In the invention, since the regulator 53 is provided to the vent gas supply system, the gas flow rate is controlled by controlling the secondary pressure of the regulator. However, in a case of using a mass flow controller instead of the regulator, the vent gas flow rate can be determined easily based on the volume of the lock chamber and the aimed value of the vent time. In such a case, repetition for the control and the measurement as shown in FIG. 16 are no more necessary. However, this involves a disadvantage that the mass flow controller requires higher apparatus cost compared with the regulator.

### Embodiment 5

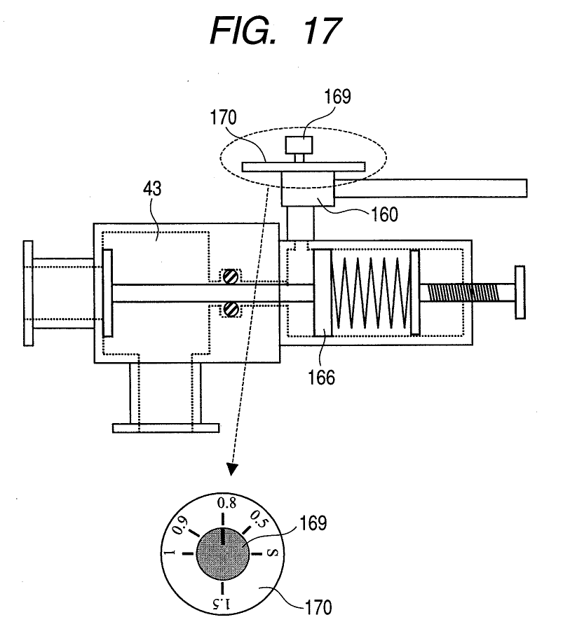

In the foregoing explanation, the open speed variable type valve capable of automatically controlling the OPEN speed is used but the valve of manually setting the OPEN speed may also be used. In this case, control for the OPEN speed shown in FIG. 16 results in a drawback of requiring troublesome manual control for the valve OPEN speed. As a method of moderate the drawback more or less, the valve OPEN speed may be preferably indicated on a scale. An example is shown in FIG. 17. The open speed variable type valve 43 shown in FIG. 17 is a valve that conducts on-off operation by pressurized air and the basic constitution is identical with that in FIG. 1B except for controlling the speed controller manually instead of using the motor. In the example of FIG. 17, a scale 170 is indicated on a knob portion 169 of the speed controller 160. That is, when the exhaust speed is measured by using an apparatus equivalent to an actual apparatus and examining a relation between the scale and the exhaust speed, the scale for each of open speed variable type valves may be set to an identical value when plural apparatus are manufactured. The valve such as shown in FIG. 17 has an advantage that the cost is inexpensive.

### Embodiment 6

The foregoing descriptions are directed to the plasma processing apparatus but the invention is applicable also to a sample inspection apparatus having a vacuum chamber. That is, in an inspection apparatus including a vacuum chamber for sample inspection connected with an evacuation vacuum pump, a vacuum transfer system and an atmospheric transfer system, in which the vacuum transfer system and the atmospheric transfer system are connected by way of a lock chamber, the lock chamber has an exhaust system including the open speed variable type valve and the open speed variable type valve may be controlled upon conducting depressurization for the lock chamber in the same manner as the embodiments described already.

What is claimed is:

1. A vacuum processing apparatus comprising:
a vacuum chamber;
a vacuum pump for depressurization of the vacuum chamber;
a valve disposed in the midway of an exhaust line for connecting the vacuum pump and the vacuum chamber; and
a controlling device for controlling the opening degree of the valve,
wherein the exhaust line is composed of only one line, and the valve disposed in the midway of the exhaust line is composed of only one open speed variable type valve,
wherein the controlling device controls the depressurization speed substantially constant upon depressurization of the vacuum chamber from the atmospheric state for the pressure of the vacuum chamber just after starting depressurization to about 50 kPa, and controls the opening degree of the valve such that the depressurization speed is 80 kPa/s or lower.

2. The vacuum processing apparatus according to claim 1, wherein the depressurization speed is 60 kPa/s or higher.

3. A vacuum processing apparatus comprising:
a lock chamber disposed between a vacuum processing chamber and an atmospheric transfer device;
a vacuum pump for depressurization of the lock chamber;
a valve disposed in the midway of an exhaust line for connecting the vacuum pump and the lock chamber; and
a controlling device for controlling the opening degree of the valve,
wherein the exhaust line is composed of only one line, and the valve disposed in the midway of the exhaust line is composed of only one open speed variable type valve,
wherein the controlling device controls the opening degree of the valve upon depressurizing the inside of the lock chamber from the atmospheric state, such that the depressurization speed is 80 kPa/s or lower when a sample is present in the lock chamber and controls the depressurization speed higher in a case where the sample is not present in the lock chamber compared with the case where the sample is present.

4. A vacuum processing apparatus comprising:
a lock chamber disposed between a plurality of vacuum processing chambers and an atmospheric transfer device;
a vacuum pump for depressurization of the lock chamber;
a valve disposed in the midway of an exhaust line for connecting the vacuum pump and the lock chamber; and
a controlling device for controlling the opening degree of the valve,
wherein the exhaust line is composed of only one line, the valve disposed in the midway of the exhaust line is composed of only one open speed variable type valve, and a plurality of samples are processed continuously by using the plurality of vacuum processing chambers,
wherein the controlling device changes the depressurization speed in the lock chamber in accordance with the transfer state of samples upon depressurizing the inside of the lock chamber from the atmospheric state, and controls the opening degree of the valve such that the depressurization speed is 80 kPa/s or lower.

5. The vacuum processing apparatus according to claim 4,
wherein the lock chamber includes a load lock chamber and an unload lock chamber,
wherein each of the load lock chamber and the unload lock chamber is connected only by way of one exhaust line with the vacuum pump, and
wherein the valve is disposed in the midway of each of the exhaust lines.
